(19) United States
(12) Patent Application Publication
(10) Pub. No.: US 2005/0174268 A1
(43) Pub. Date: Aug. 11, 2005

(54) Packing and unpacking for variable number of bits

(76) Inventor: Rafael Peset Llopis, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/515,454

(22) PCT Filed: Apr. 29, 2003
(86) PCT No.: PCT/IB03/01735

(30) Foreign Application Priority Data
May 24, 2002 (EP) 02077033.5

(51) Int. Cl. H03M 7/00

(52) U.S. Cl. 341/60

(57) ABSTRACT

A method of packing a variable number of bits from an input bit stream into an output bit stream, comprising the steps of: defining a maximum number n of bits which are to be packed into the output bit stream within a clock cycle, providing a validation bit stream which defines positions of those bits in said input bit stream as output bits which are to be selected for packing; selecting the output bits and adding only the output bits to said output bit stream.

The invention relates to packing a variable number of bits from an input bit stream into an output bit stream. The invention further relates to unpacking a variable number of bits from a bit stream.

The task of a packer is to pack a variable number of bits into a bit stream. The document EP 0 390 310 A2 discloses a data packer which receives n-bit wide parallel data words and outputs m-bit wide parallel data words, where n is a variable and may change during the operation, and m is a fixed integer.

U.S. Pat. No. 5,079,548 discloses a data packer intended to successively packing the coats having variable length with no gaps in to successive units of bits having a predetermined length.

U.S. Pat. No. 4,667,305 discloses a data processing system including a variable width data bus for the parallel transmission of data in variable width fields or blocks between units in the data processing system where the data is described by a start position and a length and an alignment is performed in case the data field is greater than the number of bit positions available on the data bus.

It is an object of the invention to provide advantageous packing or unpacking a variable number of bits to or from a bit-stream. To this end, the invention provides a method of packing, a method of unpacking, a packer, an unpacker, a computer program product, a transmitter and a receiver as defined by the independent claims. Advantageous embodiments are defined by the dependent claims.

A method of packing a variable number of bits from an input stream into an output bit stream according to a first aspect of the invention starts by defining a maximum number n of bits which are to be packed into the output bit stream within a clock cycle and further comprises providing a validation bit stream which defines positions of those bits in said input bit stream as output bits which are to be selected for packing, selecting the output bits and adding only the output bits to said output bit stream. The bits which have not been selected are not packed into the output bit stream because they do not contain relevant information.

The unpacking method corresponds to the packing method, but removes a number of bits from a bit string. Again a validation bit stream is used to define positions of those bits in said bit stream as remove a bit which are selected for unpacking. Only the selected removal bits are then removed from the bit stream.

In a preferred embodiment the packing and unpacking methods can be performed in a modular way. For the example, in the case of a n bit packer, it consists of n rows of shift units which can be shifted over a single bit position.

The packer and unpacker, respectively, comprise control means for defining a maximum number n of bits which are to be packed or unpacked within a clock cycle and means for providing a validation bit streams having the characteristics outlined above. A selector selects the desired bits and adds them to an existing output bit stream in the case of packing or removes them from a bit stream in the case of unpacking.

The methods of packing and unpacking a variable number of bits can be implemented by a computer program.

New mobile multi-media applications are emerging. Among them are cellular phones with video facilities, personal computers with video cameras and information technology terminals. These kinds of applications can successfully be addressed only when they are low in power consumption and low in cost. Both can be obtained by reducing the number of components to an absolute minimum. This however requires that both the compression core as the memory which is used to store a reference image for compression should be on the same integrated circuit. The packing and unpacking according to embodiments of the present invention are advantageously applied in such applications.

The invention is advantageous in the context of embedded compression, in particular in scalable compression in front of a loop memory, such as described in WO01/17286-A1.

The invention will now be further explained with reference to the accompanying drawings in which

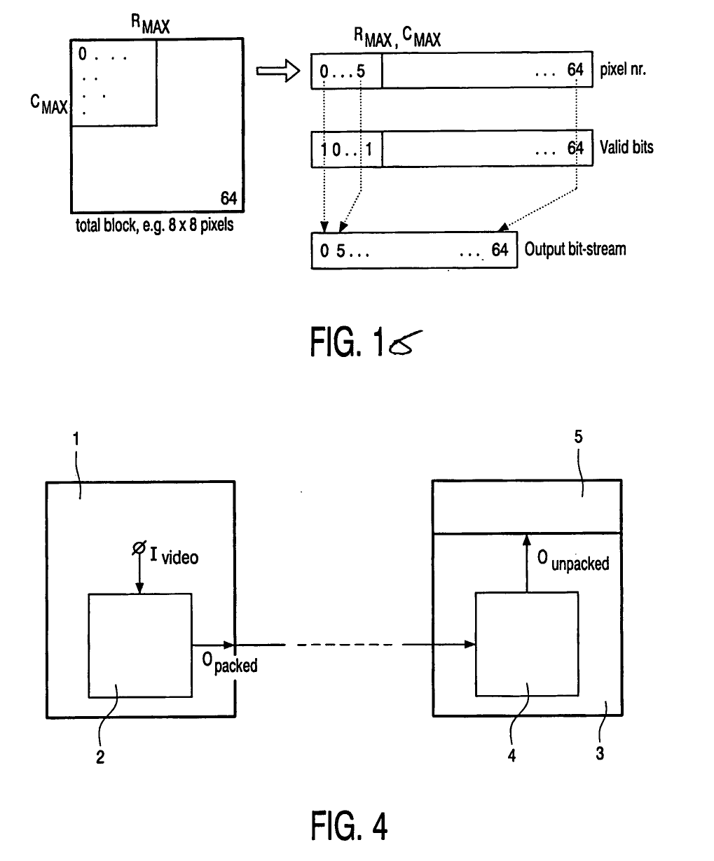

FIG. 1 shows a schematic diagram showing the packing process according to an embodiment of the invention;

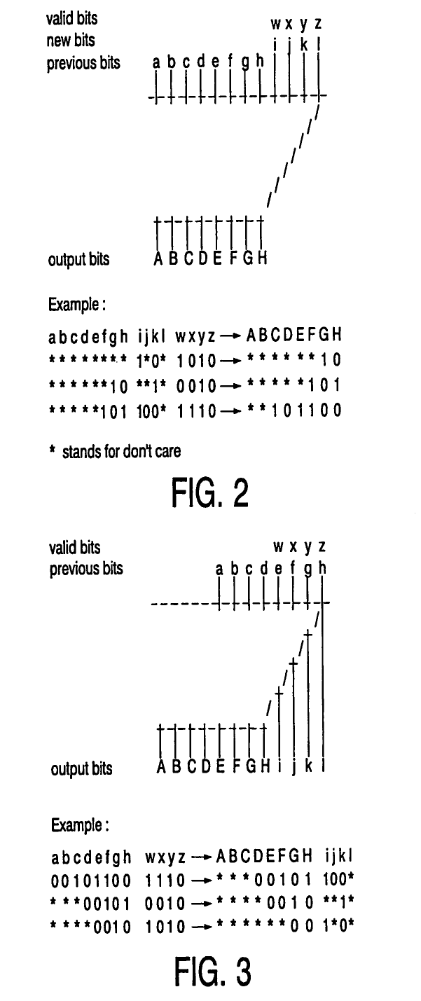

FIG. 2 shows an illustration explaining the process of FIG. 1 further by way of examples,

FIG. 3 is an illustration for an unpacking process according to an embodiment of the invention; and

FIG. 4 is a schematic block diagram of an application of the present invention.

FIG. 1 uses a total block of e.g. 8×8 pixels which is converted in a string form. A second string is provided carrying the validation bit or valid bits, where values of 1 indicate the positions in the input bit stream which shall be packed into the output bit stream. For example, pixels nr. 0, 5 and 64 are selected by the respective validation bits. Thereby, the packing behaviour is regularised, and data dependencies are reduced. Even though the embodiment has been described with a conversion of the block in a string, this conversion is not a requirement. Instead, the block structure can be directly processed by using a packer having n bits units in its validation string.

FIG. 2 illustrates by way of examples the selection of output bits. The input bit stream already consists of a string “abcdefgh”. It is assumed that a maximum of 4 bits can be packed per block cycle. Which bits have to be packed is indicated by the validation bits wxyz. In this case, there is no coincidence between the validation bits and the new bits, so that the output bit stream consists of “ABCDEFGH”. Whenever new bits arrive, the inputs present in the input bit stream are shifted left in order to create the required space for the new bits.

In a first specific example, the new bits are 1*0*, and the validation bits are 1010. Accordingly, only the first and third bit from the new bits are selected and added to the input stream as 10 at the end thereof. In the second specific example, since only the third of the new bits is selected according to the validation sequence, 1 is added to the previous input bit stream resulting in 101 as final three bits. Similarly, in the third specific example, the first three new bits are added to the previous input data stream.

FIG. 3 illustrates the unpacking process by examples. If there is coincidence of a bit string to be processed with the validation string wxyz, jklh are removed from the bit stream. In the first specific example, according to the validation string, the last three bits are removed from the string, in the second example, the last bit is removed, in the third specific example those digits at the first and third position at the end of the bit string are removed.

FIG. 4 is a block diagram illustrating an application of the present invention. A video camera 1 for a personal computer (PC camera) inputs a video signal I_{video} into a packer 2 of the present invention, where the data are compressed. The compressed data stream O_{packed} is then transmitted to the personal computer 3, where it is decompressed in unpacker 4. Finally, the unpacked data stream O_{unpacked} is used to show the video sequence on a display 5. In FIG. 4, all other components of a video camera or a personal computer which are known in the art are not shown.

Current PC cameras contain at most only limited video compression functionality. This requires a direct connection between the camera and the PC in order to transmit the video sequence. However, the available band width of this connection is not large enough to handle large image sizes at high frame rates, e.g. uncompressed VGA at 30 frames per second in 4:2:0 format requires a band width of 105 Mbit per second. High compression ratios are therefore essential. A PC camera having a wireless connection with the personal computer requires mandatorily high compression ratios due to the even more limited band width of this connection. A detachable PC camera can capture video sequences when detached from the personal computer. The video sequences are stored on a storage medium, e.g. a hard disc or solid state memory. In order to be able to store longer sequences on this internal storage medium or to reduce its capacity, a high compression ratio is essential. Embodiments of the invention provide fast and small solutions to (un)pack bits in variable length coding, which is especially advantageous in this kind of applications.

Further applications can be seen in hand-held multimedia terminals incorporating video phone functionality or in surveillance cameras which are based on a number of detachable cameras connected to an existing low band width network. Each camera records a video sequence on its local storage medium using the method of the invention. The security operator then connects to the required camera and downloads its recorded video sequence. The invention can also been applied to smart cameras with more sophisticated functionality, for example in the field of object recognition, object tracking and character recognition.

Below, computer programs are given to define the packing and unpacking process.

Packer:

LIBRARY ieee;
USE ieee. std_logic_1164. ALL;
USE ieee. numeric_std. ALL;
ENTITY packer IS

| | |
|---|---|
| GENERIC (bits | : INTEGER : = 257; |

| | |
|---|---|
| shifts | : INTEGER : = 32); |

| | | |
|---|---|---|
| PORT (clk | : IN | std_logic); |

| | | |
|---|---|---|
| data_in | : IN | signed (0 TO bits + shifts − 1); |
| valid_in | : IN | signed (bits TO bits + shifts − 1); |
| data_out | : OUT | signed (0 TO bits − 1)); |

END;
ARCHITECTURE rtl OF packer IS
BEGIN

pack: PROCESS (data_in, valid_in)
VARIABLE tmp_bits : signed (0 TO bits + shifts − 1);
BEGIN

tmp_bits : = data_in;
FOR i IN bits TO bits + shifts − 1 LOOP

IF valid_in (i) = ‘1’ AND tmp_bits (0) = ‘0’ then
tmp_bits (0 TO bits − 1) : = tmp_bits (1 TO bits − 1) & tmp_bits (i);
END IF;

END LOOP;
data out < = tmp_bits (0 TO bits − 1);

END PROCESS;

END;
Unpacker:
LIBRARY ieee;
USE ieee. std_logic_1164. ALL;
USE ieee. numeric_std. ALL;
ENTITY unpacker IS

| | | |
|---|---|---|
| GENERIC | (bits | : INTEGER : = 256; |
| | shifts | : INTEGER : = 32); |
| PORT (clk | | : IN std_logic; |

| | | |
|---|---|---|
| data_in | : IN | signed (0 TO bits − 1); |
| valid_in | : IN | signed (0 TO shifts − 1); |
| data_out | : OUT | signed (0 TO bits + shifts − 1)); |

END;
ARCHITECTUR rtl OF unpacker IS
BEGIN

unpack : PROCESS (data_in, valid_in)

VARIABLE tmp_bits : signed (0 to bits + shifts − 1);

BEGIN

tmp_bits : = data_in (0 TO bits − 1) & data_in (0 TO shifts − 1);
FOR i IN 0 TO shifts − 1 loop

IF valid_in (i) = ‘0’ THEN
tmp_bits (i + 1 TO bits + shifts − 1) : = tmp_bits (i to bits + shifts − 2);
END IF;
data_out (i) < = tmp_bits (i);

END LOOP;
data_out (shifts TO bits + shifts −1) < = tmp_bits (shifts TO bits + shifts − 1);

END PROCESS;

END;

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word ‘comprising’ does not exclude the presence of other elements or steps than those listed in a claim. The invention can be implemented by means of hardware comprising several distinct elements, and by means of a suitably programmed computer. In a device claim enumerating several means, several of these means can be embodied by one and the same item of hardware. The mere fact that certain measures are recited in mutually different dependent claims does not indicate that a combination of these measures cannot be used to advantage.

1. A method of packing a variable number of bits from an input bit stream into an output bit stream, the method comprising the steps of:
defining a maximum number n of bits which are to be packed into the output bit stream within a clock cycle;
providing a validation bit stream which defines positions of those bits in said input bit stream as output bits which are to be selected for packing;
selecting the output bits and
adding only the output bits to said output bit stream.

2. A method of unpacking a variable number of bits from a bit stream, the method comprising the steps of:
defining a maximum number of n bits which are to be unpacked from said bit stream within a clock cycle;
providing a validation bit stream which defines positions of those bits in said bit stream as removal bits which are to be selected for unpacking;
selecting the removal bits and
removing only the removal bits to said bit stream.

3. The method of claim 1 or 2, wherein said validation bit stream is built by n bit units.

4. A packer for packing a variable number of bits from an input bit stream into an output bit stream, the packer comprising:
control means for defining a maximum number n of bits which are to be packed into the output bit stream within a clock cycle;
means for providing a validation bit stream which defines positions of those bits in said input bit stream as output bits which are to be selected for packing;
a selector for selecting the output bits and
an adder which adds only the output bits to said output bit stream.

5. An unpacker for unpacking a variable number of bits from a bit stream, the unpacker comprising:
control means for defining a maximum number of n bits which are to be unpacked from said bit stream within a clock cycle;
means for providing a validation bit stream which defines positions of those bits in said bit stream as removal bits which are to be selected for unpacking;
a selector for selecting the removal bits and
means for removing only the removal bits to said bit stream.

6. The packer of claim 4 or the unpacker of claim 5, characterized in that said validation bit stream is built by n bit units.

7. A computer program product comprising computer program code means, when said program is loaded, to make a computer execute procedure to pack a variable number of bits from an input bit stream into an output bit stream by defining a maximum number n of bits, which are to be packed into the output bit stream within a clock cycle, providing a validation bit stream which defines positions of those bits in said input bit stream as output bits which are to be selected for packing, selecting the output bits and adding only the output bits to said output bit stream.

8. A computer program product comprising computer program code means, when said program is loaded, to make a computer execute procedure to unpack a variable number of bits from a bit stream by defining a maximum number n of bits which are to be unpacked from said bit stream within a clock cycle, providing a validation bit stream which defines positions of those bits in said bit stream as removal bits which are to be selected for unpacking, selecting the removal bits and removing only the removal bits to said bit stream.

9. A transmitter such as a camera system comprising:
an input unit for obtaining a video signal,
a coding unit for compressing the video signal, the coding unit comprising a packer as claimed in claim 4 for packing a variable number of bits from the video signal into an output bit stream,
an output unit for outputting the output bit stream.

10. A receiver comprising:
an input unit for receiving a coded video signal
a decoding unit for decoding the coded video signal, the decoding unit comprising an unpacker for unpacking a variable number of bits from the coded video signal to obtain a decoded video signal, and
an output unit for outputting the decoded video signal.
